(19) United States
(12) Patent Application Publication
(10) Pub. No.: US 2026/0190925 A1
(43) Pub. Date: Jul. 2, 2026

(54) MULTI-ROW CARRIER CASSETTE FOR SEMICONDUCTOR WAFERS

(71) Applicant: SINGULUS TECHNOLOGIES AG, Kahl am Main (DE)

(72) Inventors: Bianca WATTENBERG, Alling (DE); Benjamin MANDLMEIER, Pöcking (DE)

(21) Appl. No.: 19/559,232

(22) Filed: Mar. 6, 2026

Related U.S. Application Data
(63) Continuation of application No. PCT/EP2024/075002, filed on Sep. 6, 2024.

(30) Foreign Application Priority Data
Sep. 11, 2023 (DE) 10 2023 208 789.8

(51) Int. Cl. H10P 72/10; H10P 72/00; H10P 72/76

(52) U.S. Cl. CPC H10P 72/15; H10P 72/0416; H10P 72/0426; H10P 72/17; H10P 72/7614; H10P 72/7621

(57) ABSTRACT

A carrier cassette for wafers comprises two side plates facing each other in a first direction, each of which comprises a locking groove on an upper side of the same, at least one lower retaining rod mounted between the two opposing side plates, and at least two lateral retaining rods facing each other in a second direction, mounted between the two opposing side plates, and an upper locking rod that can be locked in the locking grooves of the opposing side plates to hold down wafers in the carrier cassette. The upper locking rod is configured to hold down the two rows of wafers and comprises projections configured to separate wafers of both rows adjacent in the first direction from each other when the upper locking rod is locked in the locking grooves.

### CROSS-REFERENCE TO RELATED APPLICATIONS

This application is a continuation of copending International Application No. PCT/EP 2024/075002, filed Sep. 6, 2024, which is incorporated herein by reference in its entirety, and additionally claims priority from German Application No. 10 2023 208 789.8, filed Sep. 11, 2023, which is also incorporated herein by reference in its entirety.

The present invention relates to carrier cassettes for semiconductor wafers and, in particular, carrier cassettes for semiconductor wafers that enable treatment of semiconductor wafers in batch mode. Such wafer carriers, typically also referred to as baskets or carriers, serve to place several wafers in a basin in batch mode and to treat them there with a treatment liquid.

### BACKGROUND OF THE INVENTION

Different carrier cassettes are known from conventional technology.

For example, DE 20 2015 104 876 U1 discloses a substrate carrier for solar cells comprising two opposing side plates between which side rods and bottom rods are arranged. Indentations are provided on the upper side of the side plates, into which a pressure rod can be inserted and locked by rotating the same. The side rods and bottom rods each have teeth by means of which adjacent wafers arranged between the side plates can be separated from one another. The substrate carrier is configured to receive a row of wafers between the two side plates and to hold them in the notches by locking the pressure rod.

DE 10 2015 224 980 B4 discloses a cassette for holding plate-shaped elements, which is also configured to receive a row of wafers between two side plates and is shown in FIG. 12a of the present application. The cassette comprises two side plates 2, 4, between which six receiving rods or racks 6 are arranged. The racks 6 are firmly connected to the side plates 2 and 4. A locking rod is also configured as a rack. The locking rod 8 can be locked in engagement portions 10 formed in upper sides of the side plates 2, 4. Each engagement portion 10 comprises two grooves each to which pins of the locking rod fit, so that the locking rod can be locked in the engagement portions. The side plates 2 and 4 further comprise hooks/receptacles 12 in their upper sides, which enable the cassette to be introduced into or removed from, for example, a basin.

EP 4 113 586 A 1 discloses a wafer carrier which also comprises two opposing side plates and retaining rods mounted between the opposing side plates. The side walls each comprise at least one groove for receiving at least one movable retaining rod. Thus, the wafers can be arranged one above the other in the wafer carrier, with the at least one movable retaining rod being arranged between the two wafers.

A simplified schematic cross-sectional view of a carrier cassette similar to that shown in FIG. 12a is shown in FIG. 12b. As shown schematically in FIG. 12b, the rods 6 and 8 of the basket comprise elements in the form of projections 16 that prevent adjacent wafers from touching each other, one such wafer 20 being shown in FIG. 12b. The locking rod 8 serves to prevent the wafer 20 from escaping from the carrier cassette towards the top. The locking rod 8, which can also be referred to as a downholder or pressure rod, is not permanently mechanically connected to the basket, but can be locked in the mechanism 10. A carrier cassette, as shown in FIGS. 12a and 12b, comprises only one receiving area for wafers arranged one behind the other, which is closed by the locking rod 8. The carrier cassette is configured in particular for treating square wafers.

The manufacture of solar cells involves different treatments of wafers, in particular silicon wafers, which include, among other things, etching, cleaning, and drying. Carrier cassettes are to be configured such that the wafers do not touch each other during the treatment steps, as this can result in inhomogeneities on the surface. In addition, it is needed to prevent the wafers from being lifted by reactions and reaction products during etching processes, as this can result in the loss of wafers from the carrier cassette and/or to undesirable mutual contact of the wafers.

A significant issue in the solar industry is cost pressure. Reducing wafer thickness is an important factor in lowering the cost of solar modules and, in particular, the cost per watt. The thinner the wafers become, the cheaper they are due to a corresponding reduction in the amount of silicon material. The trend is toward using material that is less than 100 μm thick, whereas the current standard thickness of M12/G12 wafers is between 170 and 150 μm. A limitation arises during wet chemical treatment. The thinner the wafers, the more they tend to stick together during the process for sticking, or the greater the distance between wafers (pitch distance) in the carrier cassette is to be selected to prevent sticking. The larger the pitch distance, the fewer wafers can be placed in a carrier cassette and the lower the throughput of a treatment machine, which ultimately results in higher costs.

During wet chemical processing, the placement of the wafers on the rods or the spacers in the form of protrusions on the rods can cause shadows on the wafers, also known as carrier marks, which are caused by flow during the etching process. These shadows are visible after wet-chemical treatment and are often considered a cosmetic defect, which can lead to problems in customer satisfaction and machine acceptance.

### SUMMARY

According to an embodiment, a carrier cassette for wafers may have: two side plates facing each other in a first direction, each of which comprises a locking groove on an upper side of the same; at least one lower retaining rod mounted between the two opposing side plates, and at least two lateral retaining rods mounted between the two opposing side plates, an upper locking rod that can be locked in the locking grooves of the opposing side plates to hold down wafers in the carrier cassette, wherein the side plates the at least one lower retaining rod, the at least two lateral retaining rods and the upper locking rod define two receiving areas for two rows of wafers extending in the first direction, the two receiving areas being arranged next to each other in a second direction perpendicular to the first direction, and the upper locking rod is configured to hold down the two rows of wafers and comprises projections that are configured to separate wafers of both rows adjacent in the first direction from each other when the upper locking rod is locked in the locking grooves.

Another embodiment may have a method for using an inventive carrier cassette, wherein two rows of wafers are placed next to each other in the carrier cassette.

According to another embodiment, a method for treating wafers with a treatment liquid using an inventive carrier cassette may have the steps of: placing two rows of wafers next to each other in the carrier cassette; locking the upper locking rod in the locking grooves to hold down the two rows of wafers with the locking rod; introducing the carrier cassette with the wafers into a bath with the treatment liquid to subject the wafers to a treatment with the treatment liquid.

According to embodiments, a carrier cassette for wafers comprises: two side plates facing each other in a first direction, each of which comprises a locking groove on an upper side of the same, at least one lower retaining rod mounted between the two opposing side plates, at least two lateral retaining rods opposing each other in a second direction and mounted between the two opposing side plates, and an upper locking rod that can be locked in the locking grooves of the opposing side plates to hold down wafers in the carrier cassette. The side plates, the lower retaining rod, the at least two lateral retaining rods, and the upper locking rod define two receiving areas for two rows of wafers extending in the first direction, the two receiving areas being arranged next to each other in the second direction. The upper locking rod is configured to hold down the two rows of wafers and comprises projections that are configured to separate wafers of both rows adjacent in the first direction from each other when the upper locking rod is locked in the locking grooves.

According to the invention, two receiving areas for two rows of wafers are thus provided next to each other in the horizontal direction in the carrier cassette, which makes it possible to provide a common upper locking rod for both receiving areas. This allows for a simple design of a carrier cassette in which two rows of wafers arranged next to each other can be held in the carrier cassette by a common locking rod during treatments such as those that occur in the manufacture of solar cells, e.g., etching, cleaning, or drying. The projections in the locking rod can prevent the wafers from touching each other during the treatment steps, thus preventing inhomogeneities on the surface.

In embodiments, the projections of the locking rod can comprise a first row of projections configured to separate wafers of one of the two rows adjacent in the first direction from each other, and a second row of projections configured to separate wafers of the other of the two rows adjacent in the first direction from each other. The projections of the first row of projections can extend at a first angle from the upper locking rod, and the projections of the second row of projections can extend at a second angle from the upper locking rod. Providing separate rows of projections for the individual rows of wafers makes it possible to reduce the amount of material needed for the projections and to prevent mutual contact between adjacent wafers of both rows.

In embodiments, the projections can comprise a row of projections, each of which is configured to separate wafers of both rows adjacent in the first direction from each other. In such embodiments, the locking rod can have a simple structure while preventing mutual contact between adjacent wafers in the two horizontally adjacent rows.

In embodiments, the carrier cassette further comprises means for separating the two receiving areas from each other in the second direction. Such means can be provided in addition to the retaining rod. The means for separating can limit the first receiving area and the second receiving area on the sides facing each other.

In embodiments, the means for separating the two receiving areas comprise a central retaining rod that is mounted between the side plates and separates the two receiving areas from each other in the second direction. In such examples, the central retaining rod can comprise projections to separate wafers of the two rows of wafers adjacent in the first direction from each other. Such embodiments make it possible to hold the wafers stably within the two receiving areas, since rods can be provided that limit the respective receiving area on all four sides.

In embodiments, the lower retaining rod can comprise a continuous or interrupted ridge that is configured to separate wafers adjacent in the second direction from each other. The ridge represents the means for separating the two receiving areas in the second direction. In other words, the lower retaining rod can comprise the means for separating the wafers of the two rows of wafers adjacent in the horizontal direction from each other. This reliably prevents contact between wafers of the first row and wafers of the second row.

In embodiments, the lower retaining rod is configured to limit both receiving areas towards the bottom. Such embodiments enable a carrier cassette having a simple structure, since only one lower retaining rod is needed.

In embodiments, the carrier cassette can comprise two lower retaining rods mounted between the two opposing side plates, each of which limits one of the two receiving areas towards the bottom. In such embodiments, the stability of the wafers held in the receiving areas can be increased.

In embodiments, the at least two lateral retaining rods and/or the at least one lower retaining rod can comprise projections configured to separate wafers adjacent in the first direction from each other. In embodiments in which a lower retaining rod is provided for both rows of wafers, this retaining rod can comprise projections that are configured to separate wafers of both rows adjacent in the first direction from each other, for example by means of projections extending in different directions or by means of projections configured in a manner to separate wafers of both rows adjacent in the first direction from each other. Thus, embodiments enable the reliability with which adjacent wafers are prevented from contacting each other to be increased.

Embodiments enable the treatment of cut wafers by closing two receiving areas for the wafers in the carrier cassette by the locking rod. In embodiments, a dimension of the two receiving areas in one direction between the at least one lower retaining rod and the locking rod is twice as large as a dimension of the two receiving areas in the second direction. Thus, embodiments enable the treatment of halved wafers next to each other in one carrier cassette.

Embodiments enable the treatment of wafers with a smaller area, which enables reducing the thickness of the wafers, for example to a thickness of less than 100 μm at a small pitch distance of less than 5 μm, without the risk of adjacent wafers touching or sticking together. In embodiments, this can enable a throughput of up to 18,400 wafers per hour (wph).

Further, embodiments enable a reduction of the supporting positions of the wafers in the carrier cassette. Typical standard M12/G12 carrier cassettes comprise nine rods, resulting in nine supporting points and correspondingly nine carrier marks. Embodiments enable a reduction to four to eight rods, thereby reducing the supporting points and carrier marks accordingly.

By enabling the treatment of thinner wafers and also adjacent rows of wafers, embodiments of the invention enable an increase in throughput when treating cut wafers with a carrier cassette. Only one locking rod is needed to vertically limit two receiving portions, treatment spaces, in one carrier cassette. This results in a simplified automation effort and use of material.

In embodiments, the carrier cassette can comprise more than two receiving areas arranged next to each other in horizontal direction. In embodiments, the carrier cassette comprises several upper locking rods and the side plates each comprise several locking grooves, wherein the side plates, the lower retaining rod, the at least two lateral retaining rods, and the several upper locking rods limit more than two receiving areas for more than two rows of wafers extending in the first direction, wherein the more than two receiving areas are arranged next to each other in the second direction and wherein each of the upper locking rods is configured to hold down two rows of wafers adjacent to each other in the second direction, and wherein each of the upper locking rods comprises projections that are configured to separate wafers of the two rows adjacent in the first direction from each other when the upper locking rod is locked in two respective locking grooves. Thus, embodiments enable a further increase in throughput by configuring the carrier cassette to receive more than two rows of wafers arranged next to each other in horizontal direction.

In embodiments, the respective projections of the locking rod and/or the retaining rods are configured to position rows of wafers having a thickness of ≤160 μm, advantageously ≤100 μm, at a distance of ≤7 mm, advantageously ≤5 mm, between wafers in the first direction in the receiving areas. Thus, embodiments enable increased throughput by the option of treating thin wafers having a small distance between the same.

In embodiments, the side plates comprise receiving means on the upper side for mechanical handling of the carrier cassettes. Thus, embodiments enable automated production of wafers for solar cells by means of wet-chemical treatment of halved or multiple-cut semiconductor wafers, such as silicon wafers.

In embodiments, the carrier cassettes are configured to perform treatment of wafers in batch mode. The wafers can be semiconductor wafers, such as silicon wafers. The wafers can be halved or multiple-cut wafers. In embodiments, the wafers can be rectangular wafers obtained by halving square wafers, with one side twice as long as the other side. In embodiments, the carrier cassettes or receiving areas of the same are configured to receive two rows of such wafers upright next to each other.

Embodiments relate to the use of such carrier cassettes, in particular for treating wafers with a treatment liquid in batch mode, wherein two rows of wafers are placed next to each other in the carrier cassette.

Embodiments provide methods for treating wafers with a treatment liquid using a carrier cassette as described herein, comprising: placing two rows of wafers next to each other in the carrier cassette; locking the upper locking rod in the locking grooves to hold down the two rows of wafers with the locking rod; and introducing the carrier cassette with the wafers into a bath with the treatment liquid to subject the wafers to a treatment with the treatment liquid.

### BRIEF DESCRIPTION OF THE DRAWINGS

Embodiments of the present invention will be detailed subsequently referring to the appended drawings, in which:

FIG. 1 is a schematic illustration of an embodiment of an inventive carrier cassette;

FIGS. 2 to 5 are schematic cross-sectional illustrations of embodiments of inventive carrier cassettes;

FIGS. 6a to 6c are schematic illustrations of embodiments of upper locking rods;

FIG. 7a to 7c are schematic illustrations for explaining an embodiment of an inventive carrier cassette;

FIGS. 8a and 8b are schematic illustrations for explaining a configuration of an embodiment of a lower retaining rod;

FIG. 9 is a schematic illustration for explaining an embodiment comprising more than two rows of wafers arranged next to each other;

FIG. 10a to 10c are schematic illustrations for explaining embodiments of central retaining rods;

FIG. 11 is a schematic illustration for explaining an embodiment comprising more than two horizontal rows of wafers arranged next to each other; and

FIGS. 12a and 12b are an isometric view and a schematic cross-sectional view of a known carrier cassette.

### DETAILED DESCRIPTION OF THE INVENTION

In the following, examples of the present invention will be described in detail with reference to the accompanying drawings. It should be noted that identical elements or elements having the same functionality are provided with identical or similar reference numbers, wherein a repeated description of elements provided with the same or similar reference numbers is typically omitted. Descriptions of elements having identical or similar reference numbers can be interchangeable. The following description provides many details to provide a more thorough explanation of examples of the invention. However, it is obvious to those skilled in the art that other examples can be implemented without these specific details. Features of the various examples described can be combined with each other, unless features of a respective combination are mutually exclusive or such a combination is expressly excluded.

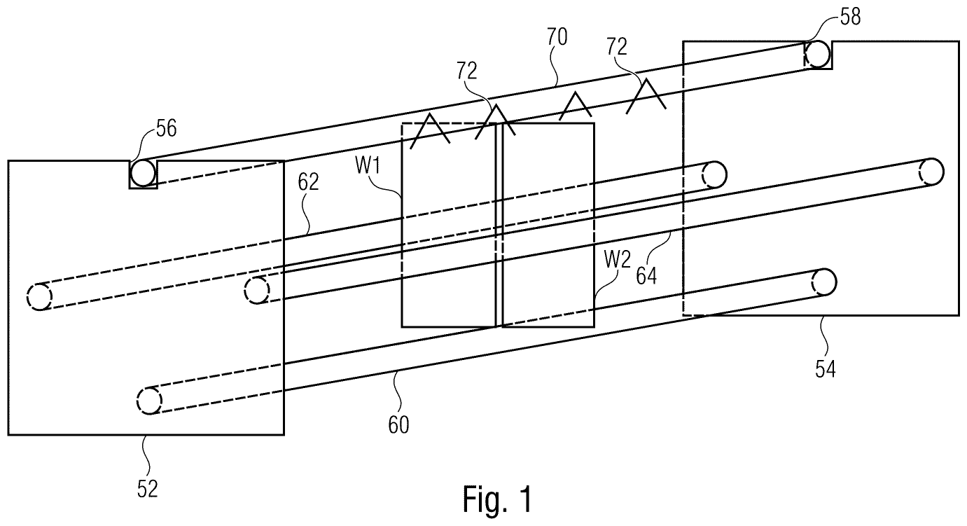

FIG. 1 shows an embodiment of a carrier cassette comprising a first side plate 52 and a second side plate 54 facing each other in a first direction. The first side plate 52 comprises a locking groove 56 on an upper side of the same, and the side plate 54 comprises a locking groove 58 on an upper side of the same. A lower retaining rod 60 extending in the first direction is provided between the side plates 52 and 54. The lower retaining rod 60 is firmly mounted on the first side plate 52 and the second side plate 54. Further, two lateral retaining rods 62 and 64 are provided between the first side plate 52 and the second side plate 54. The two lateral retaining rods 62 and 64 can face each other in a second direction perpendicular to the first direction. The lateral retaining rods 62 and 64 are firmly mounted on the first side plate 52 and the second side plate 54 and thus define a rigid carrier cassette with the side plates 52 and 54 and the lower retaining rod 60,.

The carrier cassette further comprises an upper locking rod 70 that can be locked in the locking grooves 56 and 58 of the opposing side plates 52 and 54 to hold down wafers W1, W2 in the carrier cassette. Although only two wafers are shown in FIG. 1, it goes without saying that a plurality of wafers, for example more than 50 or more than 100 wafers, can be arranged next to each other in the first direction, or that the carrier cassette is configured to receive such a plurality of wafers.

The side plates 52, 54, the lower retaining rod 60, the lateral retaining rods 62, 64, and the upper locking rod 70 define two receiving areas for two rows of wafers extending in the first direction, the two receiving areas being arranged next to each other in the second direction, which is perpendicular to the first direction. For clarity, only one wafer from each of the two rows of wafers is shown in FIG. 1, wafer W1 from the first row of wafers and wafer W2 from the second row of wafers. The upper locking rod 70 is configured to hold down the two rows of wafers. For this purpose, the locking rod 70 can be arranged centrally in the second direction. The locking rod has dimensions in the second direction such that the same comes into contact with both rows of wafers at the same time when the same is locked in the locking grooves 56, 58. The locking rod 70 comprises projections 72 that are configured to separate wafers of both rows adjacent in the first direction from each other when the upper locking rod 70 is locked in the locking grooves 56 and 58.

Since the extension of the carrier cassette in the direction between the two side plates 52 and 54 is generally greater than in the second direction perpendicular thereto, the first direction is hereinafter also referred to as the longitudinal direction for the sake of simplicity, while the second direction is hereinafter also referred to as the transverse direction for the sake of simplicity. The direction perpendicular to the longitudinal direction and the transverse direction between the lower retaining rod 60 and the locking rod 70 is also referred to as the vertical direction for the sake of simplicity. The vertical direction can correspond to the direction in which the carrier cassette is immersed into a wafer bath and removed from the wafer bath.

The first receiving area is limited in the transverse direction on the outer side by the lateral retaining rod 62, on the upper side by the locking rod 70, and on the lower side by the lower retaining rod 60. The second receiving area is limited on the outer side by the lateral retaining rod 64, on the upper side by the locking rod 70, and on the lower side by the lower retaining rod 60. In the longitudinal direction, the two receiving areas are limited by the respective side plates 52 and 54. The retaining rod 70 can be configured to limit the receiving areas on the side facing each other, for example by means of parts of the retaining rod 70 that protrude between wafers spaced apart in the transverse direction. As explained below, additional means can be provided to limit the receiving areas on the inner side, i.e., to separate wafers adjacent in the transverse direction from each other. In examples, such limiting means can be formed by a continuous or interrupted ridge on the lower retaining rod, or by one or more central retaining rods provided between the receiving areas and firmly connected to the side plates.

The projections 72 are provided to protrude into the receiving areas to separate wafers of both rows adjacent in the longitudinal direction from each other. The locking rod 70 can be configured to be locked in the locking grooves 60 and 58 by rotation, wherein in the locked state the projections 72 protrude into the receiving areas for the above-mentioned purpose. For this purpose, the locking rod and the locking grooves can be configured as described, for example, in the above-mentioned references DE 20 2015 104 876 U1 or DE 10 2015 224 980 B4. However, it goes without saying that the locking rods and locking grooves can be configured in any suitable way to enable the locking rod to be locked in the locking grooves. For example, the locking rod can comprise an oval or eccentric cross-section so that the same can be locked in a locking groove by rotation.

In order to hold down both rows of wafers, the locking rod 70 is provided in the center in transverse direction above the two receiving areas and thus above the two wafers received in the receiving areas. The dimension of the locking rod in the transverse direction is greater than the distance between the wafers W1, W2 in the locked state, at least in the areas where the wafers are to be held down, so that both wafers can be held down.

Although only one lower retaining rod 60 is shown in FIG. 1, two or more lower retaining rods can be provided in other embodiments. Although only one retaining rod 62 or 64 is provided on each side in the transverse direction in FIG. 1, more than one side rod, for example two side rods, can be provided in embodiments.

Although not shown in FIG. 1, the retaining rods 60, 62, 64 can also comprise respective projections to separate wafers in the two rows adjacent in the longitudinal direction from each other. The projections can be configured as disclosed in the above-mentioned references DE 20 2015 104 876 U1 and DE 10 2015 224 980 B4. For example, the retaining rods can be formed by racks comprising teeth and spaces between the same, so that one tooth each is arranged between each pair of wafers that are adjacent. The projections in the hold-down rod can also be formed by respective teeth to achieve the functionality described.

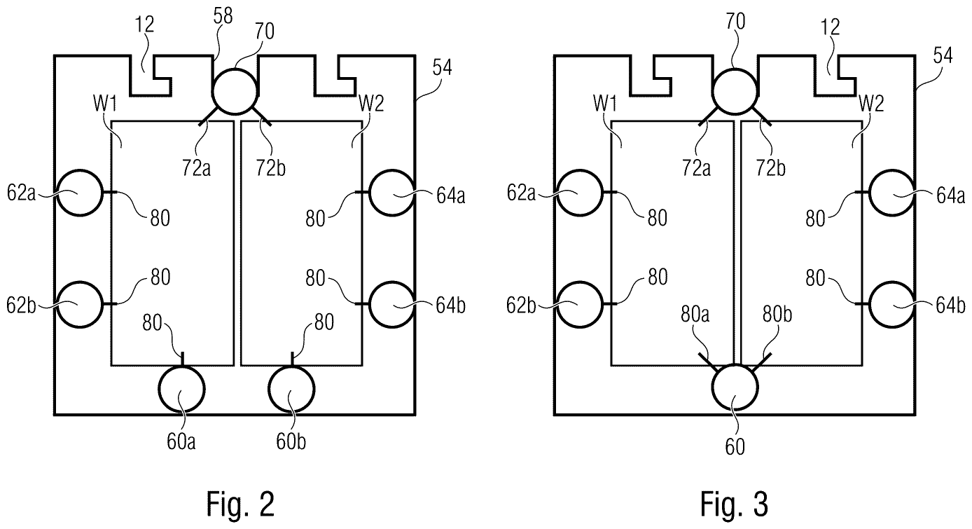

Embodiments of different arrangements of lateral and lower retaining rods are explained in more detail below with reference to FIGS. 2 to 5. FIGS. 2 to 5 illustrate schematic cross-sectional views (cross-section in the transverse and vertical directions). In the examples shown, the upper locking rod 70 comprises a first row of projections 72a and a second row of projections 72b. The first row of projections 72a protrudes into the first receiving area, in which the row of wafers to which wafer W1 belongs is arranged, and the second row of projections 72b protrudes into the second receiving area, in which the second row of wafers to which wafer W2 belongs is arranged. Receiving means 12 for mechanical handling of the carrier cassette are provided on the upper side of the side plates, for example in the form of hooks, as shown schematically.

In the embodiments shown in FIG. 2, two lateral retaining rods 62a, 62b and 64a, 64b are provided on each side in the transverse direction, which are arranged one above the other. Further, in the embodiment shown, two lower retaining rods 60a and 60b are provided. The lower retaining rod 60a limits the first receiving area towards the bottom, and the lower retaining rod 60b limits the second receiving area towards the bottom. As further shown in FIG. 2, the respective retaining rods are provided with projections 80 to separate wafers adjacent in the longitudinal direction from each other.

The embodiment shown in FIG. 3 differs from the embodiment shown in FIG. 2 in that only one lower retaining rod 60 is provided. The lower retaining rod 60 is provided in the center below the two receiving areas in the transverse direction, wherein the dimension of the retaining rod 60 in the transverse direction is greater than a distance between the wafers adjacent in the transverse direction, at least in the portions in which the wafers are to be held, so that both rows adjacent in the transverse direction can be retained together by the lower retaining rod 60. In the example shown, the lower retaining rod 60 comprises projections 80a and 80b, with the projections 80a extending into the first receiving area and the projections 80b extending into the second receiving area. Like the projections 72a and 72b, the projections 80a and 80b thus extend at different angles from the lower retaining rod 60 and the upper locking rod 70, respectively. Thus, wafers adjacent in the longitudinal direction in both rows can be separated from each other by the projections 80a, 80b.

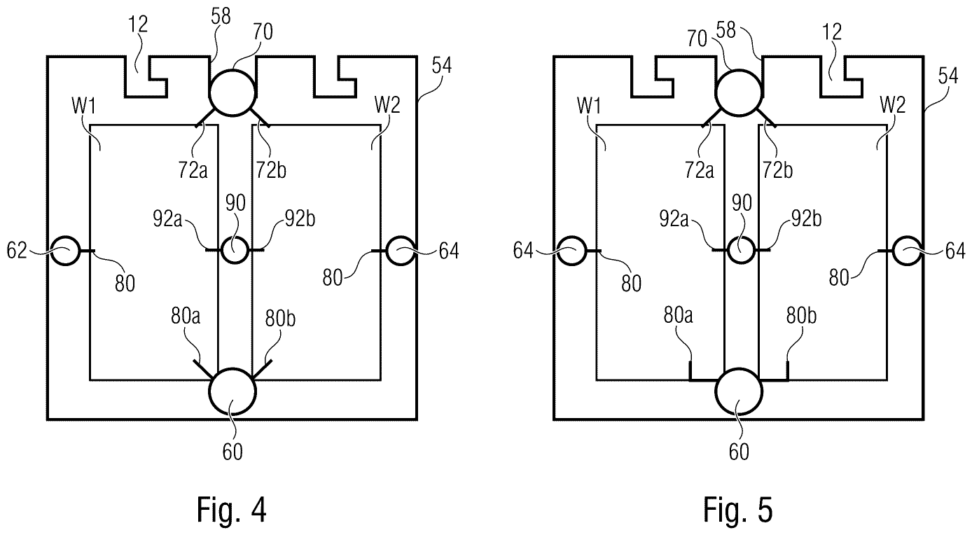

FIG. 4 shows an embodiment that differs from the embodiment shown in FIG. 3 in that only one lateral retaining rod 62 and 64, respectively, is provided and that a central retaining rod 90 is provided in transverse direction between the two receiving areas. The central retaining rod 90 is provided with projections 92a and 92b. The projections 92a protrude into the first receiving area and the projections 92b protrude into the second receiving area. The projections 92a and 92b are thus configured to separate wafers of both rows adjacent in the longitudinal direction from each other. The projections 92a and 92b are optional. The central retaining rod 90 represents means to limit the two holding areas in the transverse direction on the side where they face each other. This can make it easier to ensure that wafers next to each other in the transverse direction do not touch.

The embodiment shown in FIG. 5 differs from the embodiment shown in FIG. 4 in the configuration of the lower retaining rod 60 and, in particular, in the configuration of the projections 80a and 80b. In the example shown, the projections comprise a portion extending in the transverse direction and a portion extending in the vertical direction, with at least the portion extending in the vertical direction protruding into the first and second receiving areas. In such embodiments, the portion of the projections extending in the transverse direction can also be continuous to provide a support for the wafers and thereby hold them from below.

As can be seen in FIGS. 2 to 5, in the embodiments in which a central retaining rod is provided, the diameter of the lateral and central retaining rods can be smaller than in the embodiments in which no central retaining rod is provided, so that the external dimensions of the carrier cassettes are the same.

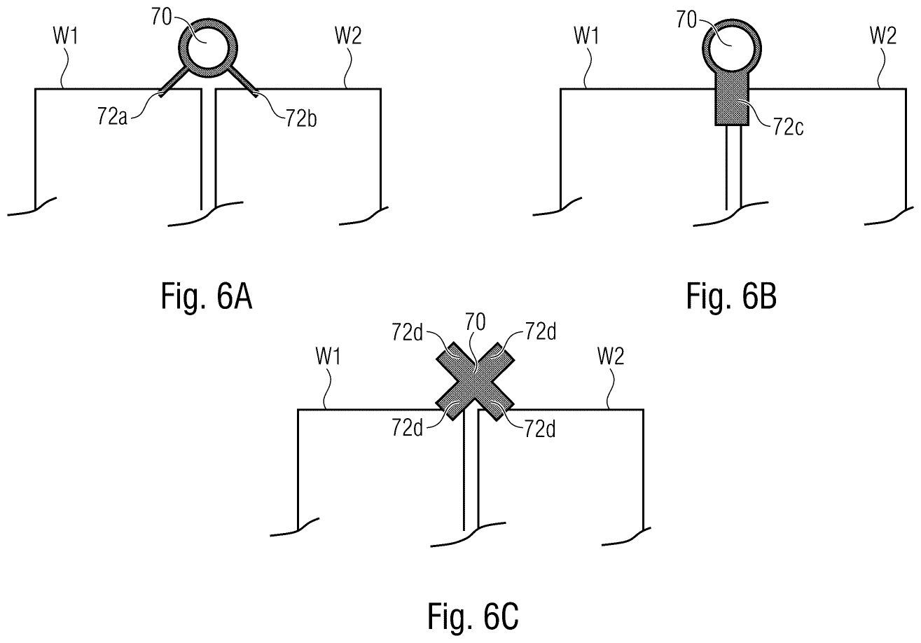

With reference to FIGS. 6a to 6c, embodiments are described how the upper locking rod can be implemented.

In the example shown in FIG. 6a, the upper locking rod comprises two rows of projections 72a and 72b, as described above. The projections 72a and 72b extend in different directions from the locking rod 70 and each protrude into the space between two wafers adjacent in the longitudinal direction to separate the same from each other. The projections 72a and 72b can be formed by respective teeth. For example, an angle of 90° can be formed between the projections 72 a and 72 b, with one projection extending at an angle of 45° with respect to the vertical direction and one projection extending at an angle of −45° with respect to the vertical direction.

According to FIG. 6b, the locking rod 70 comprises a series of projections 72c, each of which is configured to separate wafers of both rows adjacent in the first direction from each other. For this purpose, each of the individual projections 72c is configured to protrude into the space between wafers of both rows adjacent in the longitudinal direction so that the wafers of both rows can be separated from each other. In other words, each projection has a dimension in the transverse direction that is greater than the distance between wafers adjacent in the transverse direction.

According to FIG. 6c, the locking rod 70 comprises four rows of projections 72d, each extending at a 90° different angle from the locking rod 70. This embodiment allows for increased flexibility in the orientation of the locking rod 70 relative to the receiving areas and thus the wafers. If the respective projections are sufficiently wide, the wafers adjacent in the longitudinal direction can be separated from each other, regardless of the orientation of the rod 70 relative to the receiving areas.

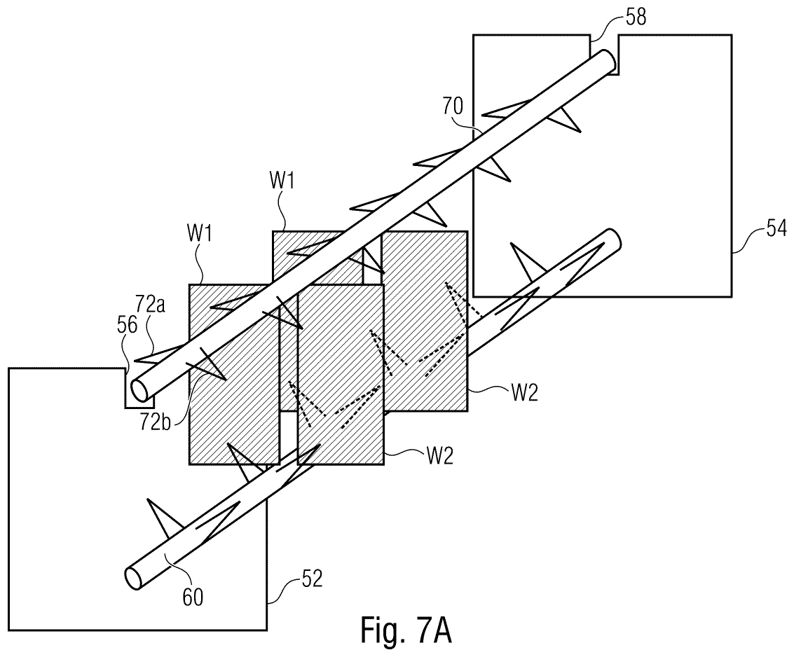

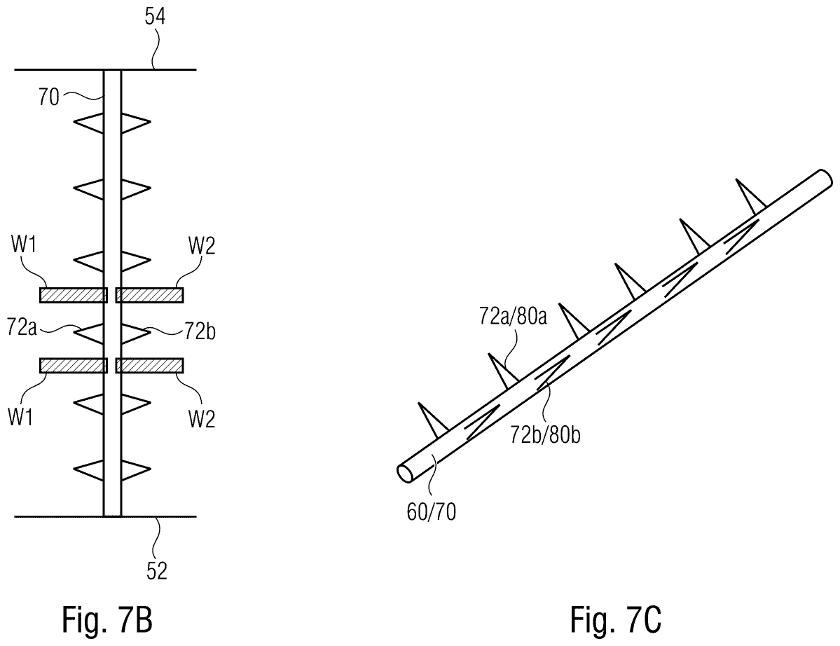

For illustration purposes, FIGS. 7a to 7c show a schematic perspective view of the example shown in FIG. 3, but the lateral retaining rods are omitted for clarity. As can be seen in FIG. 7a, the projections 72a and 72b are configured as teeth that extend in different directions from the locking rod 70. FIG. 7b shows a schematic top view, wherein for the sake of simplicity only two wafers W1 of the first row of wafers and two wafers W2 of the second row of wafers are shown. A respective tooth 72a is arranged between two wafers W1 of the first row, and a respective tooth 72b is arranged between two wafers W2 of the second row. FIG. 7c shows a perspective view of a retaining rod or locking rod, which can be the retaining rod 60 or the locking rod 70 or at least a portion of the locking rod 70. As shown, the respective projections extend in two different directions from the rod so that the same protrude into the respective receiving areas and thus between the wafers adjacent in the longitudinal direction. It should be noted that in embodiments, the locking rod and the lower retaining rod 60 can comprise a substantially identical structure with regard to the projections.

In embodiments, the projections of the retaining rods can comprise a shark tooth design, while the projections of the locking rod can comprise a fish bone design. If the lower retaining rod also serves to hold more than one row of wafers, the same can also comprise a fish bone design.

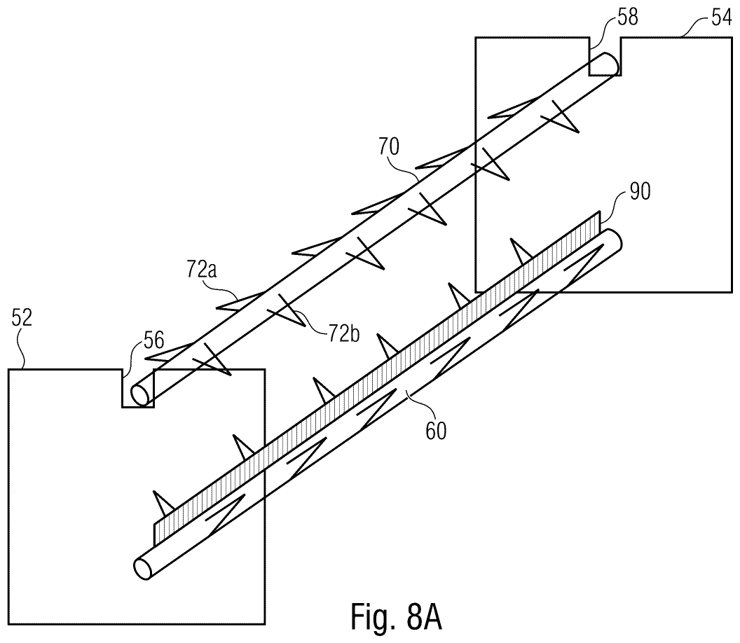

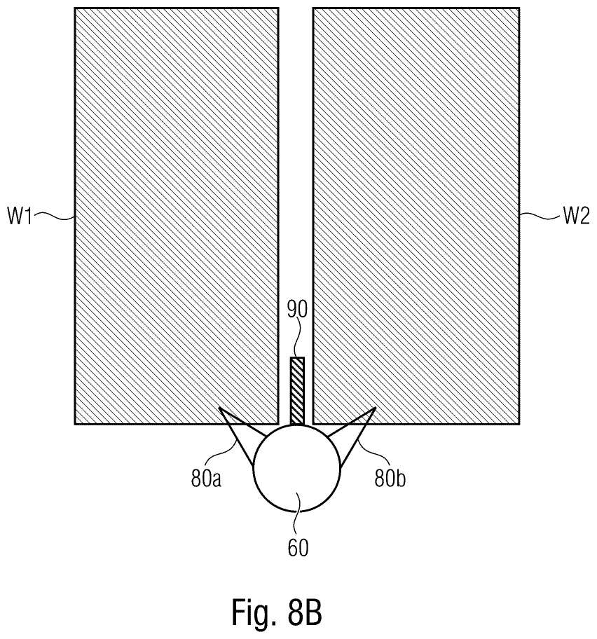

Another embodiment is described with reference to FIGS. 8a and 8b. The example shown in FIGS. 8a and 8b differs from the example described with reference to FIGS. 7a to 7c in the configuration of the lower retaining rod 60. In the example shown in FIGS. 8a and 8b, the lower retaining rod 60 comprises a continuous ridge 94 which is configured to separate the wafers W1 and W2 adjacent in the transverse direction from each other. For this purpose, the ridge 94 protrudes into a space between the wafers W1 and W2 adjacent in the transverse direction. In other words, the ridge protrudes from the lower retaining rod 60 toward the locking rod 70. The ridge 94 thus limits the two receiving areas towards the inside, i.e., between the two rows of wafers. In embodiments, the ridge can also comprise interruptions as long as the same is provided in the areas where wafers are opposite each other in the transverse direction. The ridge 94 thus provides a means for separating wafers adjacent to each other in the transverse direction.

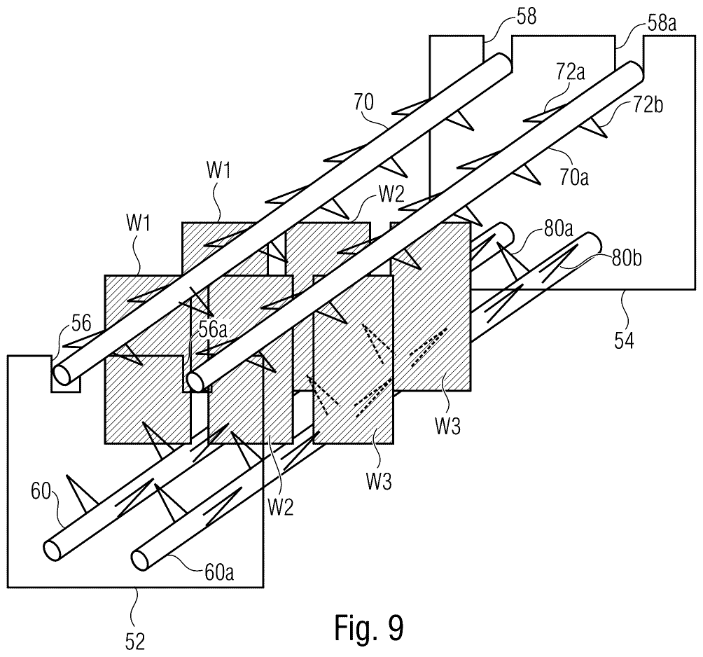

FIG. 9 shows a schematic perspective view of an embodiment that differs from the embodiments shown in FIG. 7a in that the carrier cassette is configured to receive three rows of wafers adjacent in the horizontal direction. As shown in FIG. 9, the first side plate 52 comprises a further locking groove 56a on its upper side, and the second side plate 54 comprises a further locking groove 58a on its upper side. Further, a further upper locking rod 70a is provided, which can be locked in the locking grooves 56a and 58a. The further locking rod 70a is configured to hold down the row of wafers W2 and a further row of wafers W3. Further, the further locking rod 70a again comprises projections which are configured to separate wafers of the two rows of wafers W2 and W3 adjacent in the longitudinal direction from each other when the upper locking rod 70a is locked in the locking grooves 56a and 58a. Further, a further lower retaining rod 60a is provided, which is fixedly mounted between the first side plate 52 and the second side plate 54. The structure of the second retaining rod 60a can correspond to the structure of the first retaining rod 60 comprising corresponding projections 80a and 80b. Similarly, the structure of the further locking rod 70a can correspond to the structure of the first locking rod 70, comprising corresponding projections 72a and 72b. In the example shown in FIG. 9, in which the lateral retaining rods are again omitted for clarity, the carrier cassette thus comprises three receiving areas defined by the two upper locking rods 70, the lower retaining rods 60 and 60a, the side plates, and the lateral retaining rods. It goes without saying that in embodiments, more than three corresponding receiving areas can be provided.

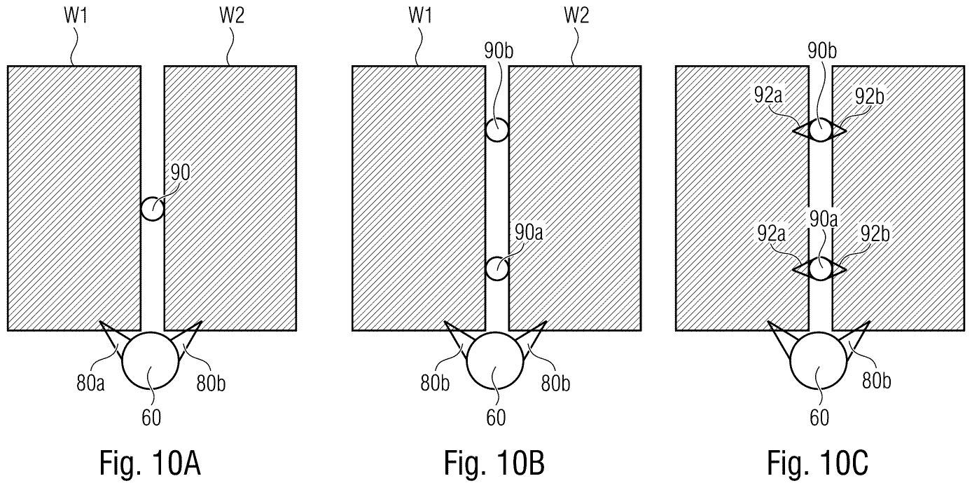

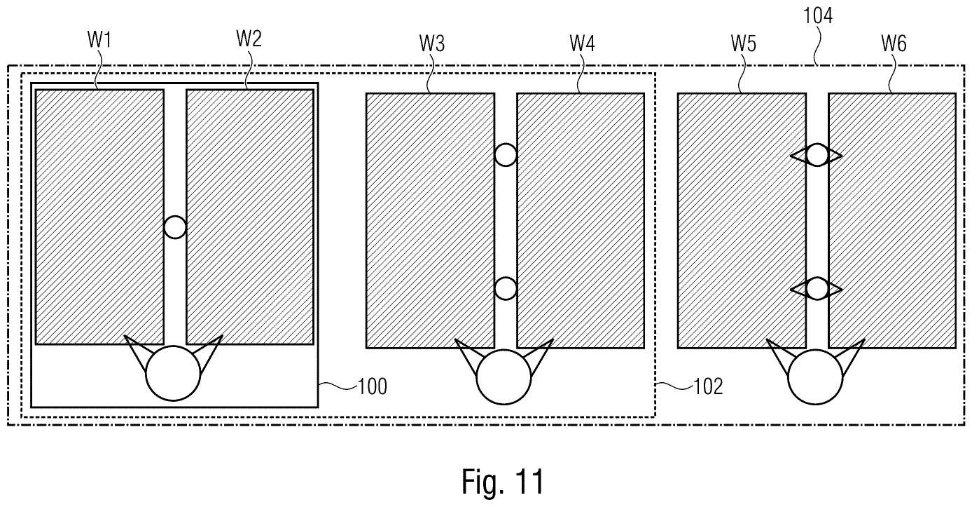

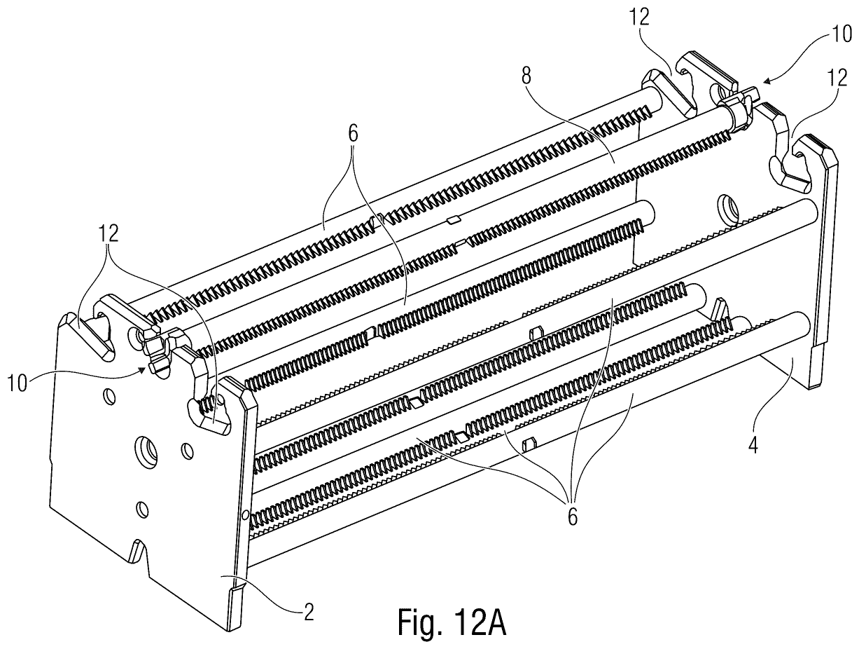

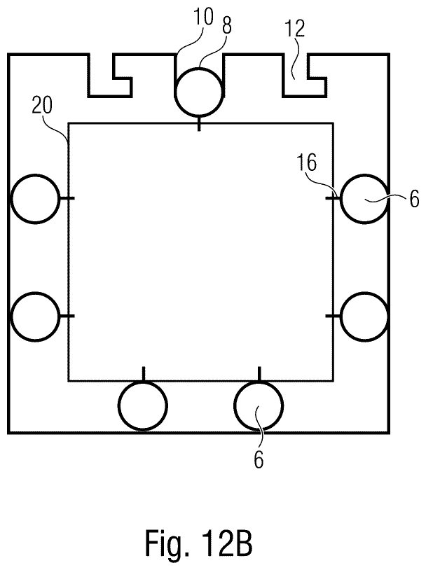

Examples of a central retaining rod for separating wafers adjacent in the transverse direction are now described with reference to FIGS. 10a to 10c.

According to FIG. 10a, a central retaining rod 90 is provided between the two receiving areas and thus between the two rows of wafers W1 and W2. The central retaining rod 90 extends from the first side plate 52 to the second side plate 54 and is attached to the same. The central retaining rod thus provides means for separating the two rows of wafers from each other. In the example shown, the retaining rod 90 comprises no projections. In alternative embodiments, the retaining rod can comprise corresponding projections 92a and 92b, as described above with reference to FIGS. 4 and 5.

The example shown in FIG. 10b differs from the example shown in FIG. 10a in that two central retaining rods 90a and 90b are provided one above the other in the vertical direction. Such an arrangement can be advantageous to more reliably prevent wafers spaced apart in the transverse direction from coming into contact with each other.

The example shown in FIG. 10c differs from the example shown in FIG. 10b in that the two central retaining rods 90a and 90b arranged one above the other comprise respective projections 92a and 92b, as explained above with reference to FIGS. 4 and 5. In embodiments, this can ensure more reliably that wafers adjacent in the longitudinal direction do not come into contact with each other.

Thus, in embodiments, means for separating are provided to separate wafers adjacent to each other in the transverse direction, wherein such means for separating can be provided, for example, in the form of a ridge of the lower retaining rod or in the form of one or more central retaining rods.

FIG. 11 shows a schematic cross-sectional view to illustrate how a carrier cassette can be expanded. A solid line 100 schematically shows a side wall for a carrier cassette for two rows of wafers W1 and W2, a dashed line 102 schematically shows a side wall for a carrier cassette for four rows of wafers W1 to W4, and a dot-dashed line 104 schematically shows a side wall for a carrier cassette for six rows of wafers W1 to W6. In principle, carrier cassettes can be expanded as desired. Although different designs of the central retaining rods are shown in FIG. 11, it goes without saying that this does not constitute any limitation, wherein identical or no central retaining rods can be used, and central retaining rods can also be provided between wafers W2 and W3 and/or W4 and W5.

Although specific embodiments have been described above, it goes without saying that the features of the embodiments can be combined with each other, unless otherwise explicitly stated. For example, the carrier cassette shown in FIG. 1 can be implemented comprising all the features described with reference to FIGS. 2 to 10c. For example, the lower retaining rod 60 shown in FIG. 5 can replace the retaining rod shown in FIG. 3.

Thus, the present invention provides a carrier cassette, which can also be referred to as a substrate carrier, limiting, with its components, at least two receiving areas arranged next to each other, wherein the locking rod is configured such that the same limits two receiving areas in the carrier cassette towards the top, i.e., the same can hold down two rows of wafers. For this purpose, embodiments of the invention provide an apparatus for treating semiconductor wafers, including two side plates, at least one rod on each side for holding the substrates laterally, a removable rod on the upper side, and optionally further rods that segment the carrier cassette so that at least two areas for receiving substrates are provided, wherein the pressure rod is configured such that the same limits at least two receiving areas. A limitation can also be provided by a central rod firmly connected to the side plates. A corresponding apparatus can also be configured for the transport of semiconductor wafers and for the storage of semiconductor wafers. Examples enable a reduction in sticking effects, a reduction in carrier marks, an increase in throughput, an increase in customer satisfaction, and an increase in competitiveness.

Embodiments of the invention are particularly suitable for treating halved or multiple-cut silicon wafers, as they allow two cut halves to be treated next to each other in a carrier cassette in a batch mode. The treatment of cut wafers can be advantageous because it can reduce the occurrence of bending, which allows the use of thinner wafers and thus an increase in throughput.

Examples of the invention also relate to a method for using a corresponding carrier cassette, in which two rows of wafers are placed next to each other in the carrier cassette, whereupon the cassette with the wafers is immersed in a bath comprising a treatment liquid to subject the wafers to a treatment, for example etching or cleaning. Examples of the present invention thus also relate to a method for treating wafers in batch mode, in which several rows of wafers are placed next to each other in a corresponding carrier cassette and the carrier cassette is then immersed in a liquid bath for the corresponding treatment.

Although features of the invention have been described in terms of apparatus features or method features, it is obvious to those skilled in the art that corresponding features may also be part of a method or an apparatus. Thus, the apparatus may be configured to perform corresponding method steps, and the respective functionality of the apparatus may represent corresponding method steps.

In the preceding detailed description, various features were sometimes grouped together in examples to rationalize the disclosure. This type of disclosure is not intended to be interpreted as meaning that the claimed examples have more features than are expressly stated in each claim. Rather, as the following claims disclose, the object may lie in less than all of the features of a single disclosed example. Consequently, the following claims are hereby incorporated into the detailed description, wherein each claim may stand as its own separate example. While each claim may stand as its own separate example, it should be noted that although dependent claims in the claims refer back to a specific combination with one or more other claims, other examples also include a combination of dependent claims with the object of any other dependent claim or a combination of any feature with other dependent or independent claims. Such combinations are included unless it is stated that a specific combination is not intended. It is further intended that a combination of features of a claim with any other independent claim is also encompassed, even if that claim is not directly dependent on the independent claim.

While this invention has been described in terms of several advantageous embodiments, there are alterations, permutations, and equivalents, which fall within the scope of this invention. It should also be noted that there are many alternative ways of implementing the methods and compositions of the present invention. It is therefore intended that the following appended claims be interpreted as including all such alterations, permutations, and equivalents as fall within the true spirit and scope of the present invention.

1. A carrier cassette for wafers, comprising:
two side plates facing each other in a first direction, each of which comprises a locking groove on an upper side of the same;
at least one lower retaining rod mounted between the two opposing side plates, and at least two lateral retaining rods mounted between the two opposing side plates,
an upper locking rod that can be locked in the locking grooves of the opposing side plates to hold down wafers in the carrier cassette,
wherein
the side plates the at least one lower retaining rod, the at least two lateral retaining rods and the upper locking rod define two receiving areas for two rows of wafers extending in the first direction, the two receiving areas being arranged next to each other in a second direction perpendicular to the first direction, and
the upper locking rod is configured to hold down the two rows of wafers and comprises projections that are configured to separate wafers of both rows adjacent in the first direction from each other when the upper locking rod is locked in the locking grooves.

2. The carrier cassette according to claim 1, wherein the projections comprise a first row of projections configured to separate wafers of one of the two rows adjacent in the first direction from each other, and a second row of projections configured to separate wafers of the other of the two rows adjacent in the first direction from each other.

3. The carrier cassette according to claim 2, wherein the projections of the first row of projections extend at a first angle from the upper locking rod, and the projections of the second row of projections extend at a second angle from the upper locking rod.

4. The carrier cassette according to claim 1, wherein the projections comprise a row of projections, each of which is configured to separate wafers of both rows adjacent in the first direction from each other.

5. The carrier cassette according to claim 1, further comprising a unit for separating the two receiving areas from each other in the second direction.

6. The carrier cassette according to claim 5, wherein the unit for separating comprises a central retaining rod that is mounted between the side plates and separates the two receiving areas from each other in the second direction.

7. The carrier cassette according to claim 6, wherein the central retaining rod comprises projections to separate wafers of the two rows adjacent in the first direction from each other.

8. The carrier cassette according to claim 6, wherein the unit for separating comprises a continuous or interrupted ridge of the at least one lower retaining rod, which is configured to separate wafers adjacent in the second direction from each other.

9. The carrier cassette according to claim 1, wherein the at least one lower retaining rod is configured to limit both receiving areas towards the bottom.

10. The carrier cassette according to claim 1, comprising two lower retaining rods mounted between the two opposing side plates, each of which limits one of the two receiving areas towards the bottom.

11. The carrier cassette according to claim 1, wherein the at least two lateral retaining rods and/or the at least one lower retaining rod comprise projections that are configured to separate wafers adjacent in the first direction from each other.

12. The carrier cassette according to claim 9, wherein the at least one lower retaining rod comprises projections configured to separate wafers of both rows adjacent in the first direction from each other.

13. The carrier cassette according to claim 1, wherein a dimension of the two receiving areas in one direction between the at least one lower retaining rod and the locking rod is twice as large as a dimension of the two receiving areas in the second direction.

14. The carrier cassette according to claim 1, comprising several upper locking rods, wherein the side plates each comprise several locking grooves, wherein the side plates, the at least one lower retaining rod, the at least two lateral retaining rods, and the several upper locking rods limit more than two receiving areas for more than two rows of wafers extending in the first direction, wherein the more than two receiving areas are arranged next to each other in the second direction, and wherein each of the upper locking rods is configured to hold down two rows of wafers adjacent to each other in the second direction, and comprises projections that are configured to separate wafers of the two rows adjacent in the first direction from each other when the upper locking rod is locked in two respective locking grooves.

15. The carrier cassette according to claim 1, wherein the respective projections are configured to position rows of wafers comprising a thickness ≤160 μm, advantageously ≤100 μm, with a spacing ≤7 mm, advantageously ≤5 mm, between wafers in the first direction in the receiving areas.

16. The carrier cassette according to claim 1, wherein the side plates comprise a receiving unit on the upper side for mechanical handling of the carrier cassette.

17. A method for using a carrier cassette according to claim 1, wherein two rows of wafers are placed next to each other in the carrier cassette.

18. A method for treating wafers with a treatment liquid using a carrier cassette according to claim 1, comprising:
placing two rows of wafers next to each other in the carrier cassette;
locking the upper locking rod in the locking grooves to hold down the two rows of wafers with the locking rod;
introducing the carrier cassette with the wafers into a bath with the treatment liquid to subject the wafers to a treatment with the treatment liquid.
